(19) United States
(12) Patent Application Publication
(10) Pub. No.: US 2026/0331605 A1
(43) Pub. Date: Oct. 22, 2026

(54) Battery Module

(71) Applicant: SK On Co., Ltd., Seoul (KR)

(72) Inventors: Eun Young KIM, Daejeon (KR); Ji San KIM, Daejeon (KR); Chae Gwan KIM, Daejeon (KR); Hyun Seok KIM, Daejeon (KR); Hyo Kyu LEE, Daejeon (KR)

(21) Appl. No.: 19/468,371

(22) Filed: Feb. 3, 2026

(30) Foreign Application Priority Data
Mar. 5, 2025 (KR) 10-2025-0028324

(51) Int. Cl. H01M 10/42; H01M 10/48; H01M 50/507; H01M 50/519; H05K 1/02; H05K 1/181

(52) U.S. Cl. CPC H01M 10/4257; H01M 10/48; H01M 50/507; H01M 50/519; H05K 1/0203; H05K 1/181; H01M 2010/4271; H05K 2201/10189; H05K 2201/10219; H05K 2201/10287; H05K 2201/10522

(57) ABSTRACT

A battery module includes a plurality of battery cells, and a Battery Management System (BMS) module connected to at least one of the plurality of battery cells. The BMS module includes a substrate, a plurality of electrical components mounted on one surface of the substrate, and a cooling element disposed on the other surface, opposite to the one surface, and cooling at least a portion of the other surface.

### CROSS-REFERENCE TO RELATED APPLICATIONS

This patent document claims the priority and benefits of Korean Patent Application No. 10-2025-0028324 filed on Mar. 5, 2025, the disclosure of which is incorporated herein by reference in its entirety.

### TECHNICAL FIELD

The disclosure and implementations disclosed in this patent document generally relate to a battery module.

### BACKGROUND

Secondary batteries, unlike primary batteries, offer the convenience of rechargeability, and are attracting a lot of attention as a power source for various mobile devices, ebikes, electric vehicles and the like.

These secondary batteries may include battery cells in which an electrode assembly is formed by stacking a cathode plate, an anode plate and a separator or by winding the same in a roll shape and is accommodated within a case. Multiple battery cells may be stacked in a predetermined direction and accommodated in a battery module or battery pack.

Meanwhile, the Battery Management System (BMS) circuit board, which manages the temperature and output of battery cells, is equipped with electrical components. However, the varying heat generation of each component has difficulty in effectively cooling the component.

### SUMMARY

The present disclosure can be implemented in some embodiments to provide a battery module including a BMS circuit board capable of effective cooling.

According to an aspect of the present disclosure, components with different heat generation amounts, mounted on the circuit board, may be uniformly cooled.

According to an aspect of the present disclosure, a substrate may be divided into a high heat generation region and a low heat generation region, thereby allowing concentrated cooling of the high heat generation region.

The battery module in the present disclosure may be widely applied to devices within green technology fields such as electric vehicles, battery charging stations, and other battery-based solar and wind power generation applications. Furthermore, the battery module in the present disclosure may be used in eco-friendly electric vehicles, hybrid vehicles, and other vehicles that prevent climate change by suppressing air pollution and greenhouse gas emissions.

In some embodiments, a battery module includes a plurality of battery cells; and a Battery Management System (BMS) module connected to at least one of the plurality of battery cells. The BMS module includes a substrate; a plurality of electrical components mounted on one surface of the substrate; and a cooling element disposed on the other surface, opposite to the one surface, and cooling at least a portion of the other surface.

In an embodiment, the cooling element may be a thermoelectric device.

In an embodiment, the substrate may further include a heat transfer member disposed between the other surface and the cooling element, and the heat transfer member may include an electrically insulating material.

In an embodiment, the substrate may include a first region in which the cooling element is disposed, and a second region in which the cooling element is not disposed.

In an embodiment, the plurality of electrical components may include a high-heat generating component disposed in the first region; and a low-heat generating component disposed in the second region, and having a relatively small quantity of heat than the high-heat generating component.

In an embodiment, the high-heat generating component may include at least one of a high-voltage (HV) connector, a circuit breaker, a current sensor, and a Metal Oxide Semiconductor Field Effect Transistor (MOSFET).

In an embodiment, the low-heat generating component may include a low-voltage (LV) connector.

In an embodiment, the BMS module may further include a cooling element connection wire electrically connecting the LV connector and the cooling element.

In an embodiment, the cooling element connection wire may have one end disposed on the second region of the substrate and the other end disposed on the first region of the substrate, and is connected to the cooling element.

In an embodiment, the battery module may further include: a busbar assembly electrically connected to at least one battery cell among the plurality of battery cells; and a sensing module connected to the busbar assembly and sensing current and voltage of the at least one battery cell. The first region of the substrate may be connected to the busbar assembly, and the second region of the substrate is connected to the sensing module.

In an embodiment, the thermoelectric device may include at least one of a Peltier element, a Seebeck element, and a Thomson element.

### BRIEF DESCRIPTION OF DRAWINGS

Certain aspects, features, and advantages of the present disclosure are illustrated by the following detailed description with reference to the accompanying drawings.

FIG. 1 is a perspective view of a battery module according to an embodiment.

FIG. 2 is an exploded perspective view of a battery module according to an embodiment.

FIG. 3 is a schematic diagram of a BMS module according to an embodiment.

FIG. 4 is a cross-sectional schematic diagram of FIG. 3.

### DETAILED DESCRIPTION

Features of the present disclosure disclosed in this patent document are described by example embodiments with reference to the accompanying drawings.

Before going into the detailed description of the embodiments, the terms or words used in the following description and claims should not be interpreted as limited to their usual or dictionary meanings, but should be interpreted as having meanings and concepts that conform to the technical idea of the present disclosure based on the principle that the inventor may appropriately define the concept of the term to explain his or her own invention in the best way.

The same reference numbers or symbols described in respective drawings represent parts or components that perform substantially the same function. For the convenience of explanation and understanding, the same reference numbers or symbols may be used in different embodiments to describe the same.

In the following description, the singular expression includes the plural expression unless the context clearly indicates otherwise. It should be understood that the terms “include,” “configure,” or the like are intended to specify the presence of a feature, number, step, operation, component, part, or combination thereof described in the specification, but do not preclude the possibility of the presence or addition of one or more other features, numbers, steps, operations, components, parts, or combinations thereof.

In addition, in the following description, the expressions such as upper side, upper, lower side, lower, below, side, front, rear, and the like are expressed based on the direction depicted in the drawings, and it should be noted in advance that they may be expressed differently if the direction of the corresponding object changes.

In addition, in the following description and claims, terms including ordinal numbers such as “first”, “second,” or the like may be used to distinguish between components. These ordinals are used to distinguish between identical or similar components, and the meaning of the terms should not be limited due to the use of these ordinals. For example, components combined with these ordinals should not be limited in their use order, location order, or the like by their numbers. If necessary, respective ordinal numbers may be used interchangeably.

Hereinafter, the present disclosure will be described in detail with reference to the drawings. However, these are merely illustrative and the present disclosure is not limited to the detailed embodiments illustrated by the drawings.

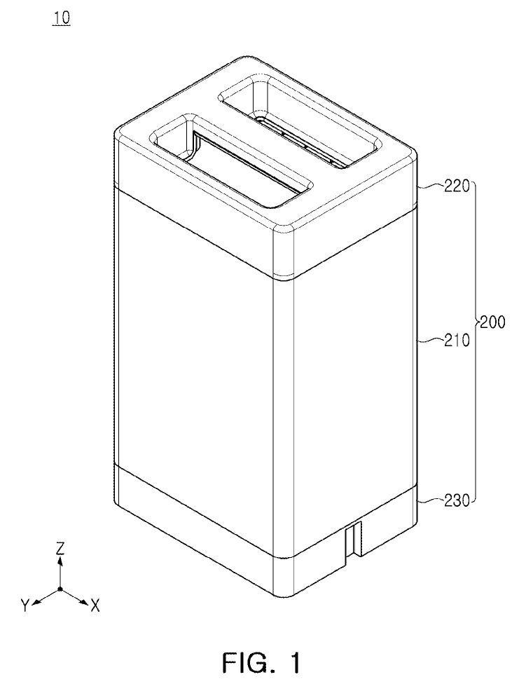

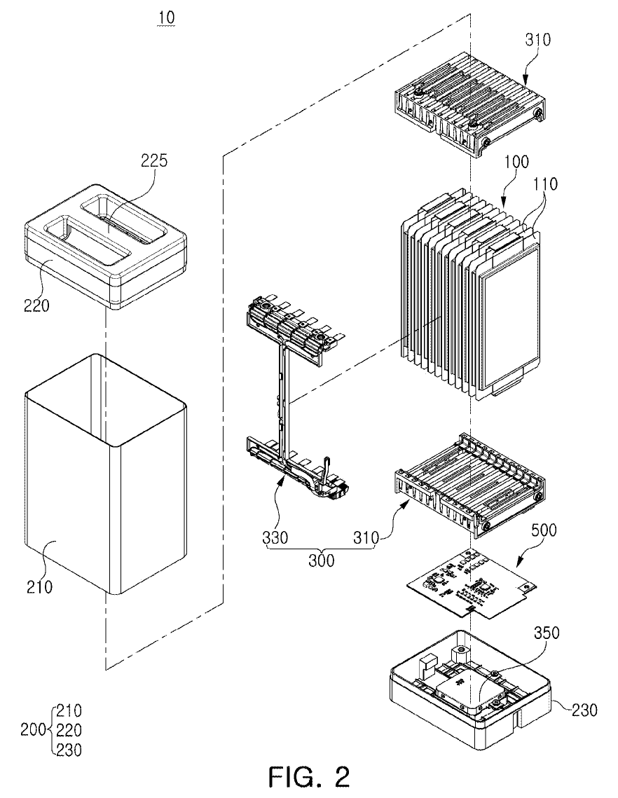

FIG. 1 is a perspective view of a battery module according to an embodiment, and FIG. 2 is an exploded perspective view of the battery module according to an embodiment.

Referring to FIGS. 1 and 2, a battery module 10 according to an embodiment may include a cell assembly 100 including a plurality of battery cells 110, a housing 200 that accommodates the cell assembly 100, a connection unit 300 electrically connected to the cell assembly 100, a Battery Management System (BMS) module 500 that is connected to the connection unit 300 and includes a control unit that controls the cell assembly 100, and a connection terminal 350 that may be connected to an external power source.

The housing 200 may accommodate the cell assembly 100 therein. The housing 200 may include a metal material such as aluminum or stainless steel to ensure mechanical strength. The housing 200 may include a case 210 that encloses the cell assembly 100 and has an opening, a first case cover 220 disposed on one side of the case 210, and a second case cover 230 disposed on the other side of the case 210. According to an embodiment, the housing 200 in the present disclosure may be mounted on an e-bike, such as an electric bicycle. In this case, the first case cover 220 may be provided with a handle 225, and the second case cover 230 may be provided with the connection terminal 350. Through this structure, the battery module 10 may be easily removable from the e-bike by the user.

The cell assembly 100 may include the plurality of battery cells 110. The plurality of battery cells may be stacked or arranged in a predetermined direction. The battery cell 110 in an embodiment may be a secondary battery including an electrode assembly (not illustrated). In addition, the battery cell 110 in an embodiment may be a lithium ion battery, but is not limited thereto. For example, the battery cell 110 may be a nickel-cadmium battery, a nickel-metal hydride battery, or a nickel-hydrogen battery capable of being charged and discharged. In addition, the battery cell 110 in an embodiment may be provided in various types depending on the shape of the cell case that accommodates the electrode assembly. For example, the battery cell 110 in an embodiment may include any one of a pouch type, a prismatic type, or a cylindrical type. Although the cell case is depicted as a pouch cell in the drawing, this is merely an example, and the present disclosure is not limited to the type, shape, or material of the cell case, or the like.

The connection unit 300 may be electrically connected to at least one of the plurality of battery cells 110. The connection unit 300 may include a busbar assembly 310 and a sensing module 330. The busbar assembly 310 may be disposed on at least one side of the cell assembly 100 and electrically connected to at least one of the plurality of battery cells 110. The busbar assembly 310 may be electrically connected to the connection terminal 350 and may be electrically connected to an external power source of the battery module 10. The sensing module 330 may be connected to the busbar assembly 310 and sense values such as current/voltage of the busbar assembly 310. The sensing module 330 may be connected to the BMS module 500 and may transmit and receive various information with the control unit.

The BMS module 500 in an embodiment may include a control unit (not illustrated). The control unit is connected to the connection unit 300 to receive values such as voltage of the cell assembly 100 and environmental values such as pressure and temperature within the housing 200, and control the cell assembly 100 based on these values. In this case, the control unit may include a BMS. Furthermore, the control unit refers to a processor or the like performing the functions described above and is not limited to detailed components.

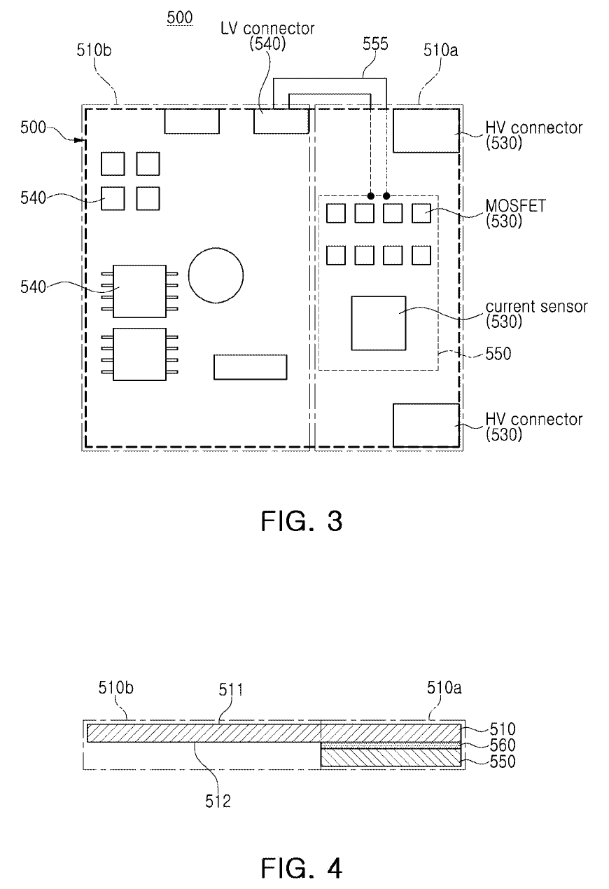

Meanwhile, the BMS module 500 may be equipped with a plurality of electrical components 530 and 540 (see FIG. 3). The electrical components 530 and 540 may have different quantities of heat depending on their functions, capacities, or the like. Effective cooling and control of the heat generated by these components is crucial. According to an embodiment of the present disclosure, heat generated in the BMS module 500 may be effectively cooled. Hereinafter, the BMS module 500 in an embodiment will be described in detail with reference to the drawings.

FIG. 3 is a schematic diagram of a BMS module according to an embodiment, and FIG. 4 is a cross-sectional schematic diagram of FIG. 3.

Referring to FIGS. 3 and 4 together, the battery module 10 in an embodiment may include the plurality of battery cells 110 and the BMS module 500 connected to at least one of the plurality of battery cells 110. In this case, the BMS module 500 may include a substrate 510, the plurality of electrical components 530 and 540 mounted on one surface 511 of the substrate 510, and a cooling element 550 disposed on the other surface 512 of the substrate 510 opposite the one surface 511 to cool the other surface 512.

According to an embodiment, the cooling element 550 may be a thermoelectric device. In detail, when current is applied to the cooling element 550, one surface of the cooling element 550 facing the other surface 512 of the substrate 510 is cooled, and heat may be generated on the other surface 552 of the cooling element 550 opposite one surface 551 of the cooling element 550. For example, the thermoelectric device may include at least one of a Peltier element, a Seebeck element, and a Thomson element. However, the thermoelectric device in the present disclosure is not limited thereto, and any material that cools at least one surface when current is applied is considered to fall within the scope of the present disclosure.

The cooling element 550 may be disposed to overlap a portion of the substrate 510. In detail, the substrate 510 may include a first region 510a where the cooling element 550 is disposed and a second region 510b where the cooling element 550 is not disposed. The first region 510a may be referred to as a “high heat generation region” or a “cooling region.” The second region 510b may be referred to as a “low heat generation region.” The plurality of electrical components 530 and 540 may be mounted on one surface 511 of the substrate 510 across the first region 510a and the second region 510b. Meanwhile, in this case, the first region 510a and the second region 510b are not physically separated, and may be determined based on whether the cooling element 550 is disposed. In detail, the first region 510a may be the region where the cooling element 550 is disposed, and may refer to a region overlapping the cooling element 550 in the thickness direction and including the periphery thereof. The second region 510b may refer to a region of the substrate 510 other than the first region 510a.

The plurality of electrical components 530 and 540 may include a high-heat generating component 530 disposed in the first region 510a (high heat generation region), and a low-heat generating component 540 disposed in the second region 510b (low heat generation region) and having a quantity of heat less than a quantity of heat of the high-heat generating component 530. For example, among the plurality of electrical components 530 and 540, the high-heat generating component 530 may be disposed in the first region 510a so that it may be actively cooled by the cooling element 550, and the low-heat generating component 540 may be disposed in the second region 510b so that it may be heat-radiated through the other surface 512 of the substrate 510. Through this arrangement structure, the BMS module 500 in an embodiment may effectively cool the heat generated from the electrical components. In addition, the electrical components may be cooled uniformly. Meanwhile, although the area of the cooling element 550 in the drawing is formed smaller than the area of the first region 510a, the present disclosure is not limited thereto, and is not particularly limited as long as the cooling element 550 is disposed to roughly overlap the first region 510a.

According to an embodiment, the high-heat generating component 530 may include at least one of a HV (High Voltage) connector, a circuit breaker, a current sensor, and a MOSFET. The HV connector may be electrically connected to the busbar assembly 310 or the connection terminal 350. Furthermore, according to an embodiment, the low-heat generating component 540 may include a LV (Low Voltage) connector. The LV connector may be connected to the sensing module 330 or the connection terminal 350. However, the above-described components are merely examples, and the present disclosure is not limited thereto.

In addition, according to an embodiment, a heat transfer member 560 disposed between the other surface 512 of the substrate 510 and the cooling element 550 may be further included. The heat transfer member 560 may be a material having high thermal conductivity and may include an electrically insulating material. Therefore, the other surface 512 of the substrate 510 may be effectively cooled by the cooling element 550. In addition, in an embodiment not illustrated, the heat transfer member 560 may be disposed across the first region 510a and the second region 510b of the substrate 510. In this case, a portion of the heat transfer member 560 disposed in the first region 510a may enable heat exchange between the substrate 510 and the cooling element 550 to be effectively performed. A portion of the heat transfer member 560 disposed in the second region 510b may effectively dissipate heat to the other surface 512 of the substrate 510.

Furthermore, according to an embodiment, the BMS module 500 may further include a cooling element connection wire 555 that supplies power to the cooling element 550. The cooling element connection wire 555 may have one end disposed on the second region 510b of the substrate 510 and the other end disposed on the first region 510a of the substrate 510. The other end of the cooling element connection wire 555 may be connected to the cooling element 550. For example, a cooling element connection wire 555 may electrically connect an LV connector and a cooling element 550. However, the method of supplying current to the cooling element 550 in the present disclosure is not limited thereto. For example, the cooling element connection wire 555 may have one end disposed on the first region 510a of the substrate and the other end connected to the cooling element 550. As another example, the cooling element connection wire 555 may have one end connected to the connection terminal 350 and the other end connected to the cooling element 550.

In this way, the BMS module 500 in an embodiment may divide the substrate 510 into two regions to effectively cool the heat generated by the substrate 510. Meanwhile, the quantity of heat generated in the substrate 510 may be proportional to the magnitude of the current and voltage passing through the substrate 510. In detail, the first region 510a of the substrate 510 may be designed to have a HV connector disposed therein and connected to the busbar assembly 310 so that a relatively high current may flow, and the second region 510b may be designed to have a LV connector disposed therein and connected to the sensing module 330 so that a relatively low current may flow. In detail, the first region 510a of the substrate 510 may be connected to the busbar assembly 310, and the second region 510b of the substrate 510 may be connected to the sensing module 330.

Furthermore, in an embodiment of the present disclosure, the electrical component 530 disposed in the first region 510a may be cooled by disposing the cooling element 550 on one surface 512 of the first region 510a of the substrate 510, thereby eliminating the need for a separate heat sink in the limited space within the battery module.

However, the present disclosure is not limited thereto, and the heat sink may be disposed on the other surface of the cooling element 550 or on the other surface 512 of the second region 510b. In detail, as long as the cooling element 550 is disposed on the other surface 512 of the first region 510a, it should be considered to fall within the scope of the present disclosure. Only specific examples of implementations of certain embodiments are described. Variations, improvements and enhancements of the disclosed embodiments and other embodiments may be made based on the disclosure of this patent document. Certain components of the above-described embodiments may be omitted, and the embodiments may be combined with each other.

The above description is merely an example of the application of the principles of the present disclosure, and other configurations may be included without departing from the scope of the present disclosure.

As set forth above, according to an aspect of the present disclosure, a battery module including a BMS circuit board capable of effective cooling may be provided.

According to an aspect of the present disclosure, a battery module in which cooling components having different quantities of heat and mounted on a circuit board may be uniformly cooled may be provided.

According to an aspect of the present disclosure, a battery module in which a high heat generation area may be intensively cooled by dividing a substrate into the high heat generation area and a low heat generation area may be provided.

What is claimed is:

1. A battery module comprising:
a plurality of battery cells; and
a Battery Management System (BMS) module connected to at least one of the plurality of battery cells,
wherein the BMS module includes,
a substrate;
a plurality of electrical components mounted on one surface of the substrate; and
a cooling element disposed on the other surface, opposite to the one surface, and cooling at least a portion of the other surface.

2. The battery module of claim 1, wherein the cooling element is a thermoelectric device.

3. The battery module of claim 1, wherein the substrate further includes a heat transfer member disposed between the other surface and the cooling element,
wherein the heat transfer member includes an electrically insulating material.

4. The battery module of claim 1, wherein the substrate includes a first region in which the cooling element is disposed, and a second region in which the cooling element is not disposed.

5. The battery module of claim 4, wherein the plurality of electrical components include,
a high-heat generating component disposed in the first region; and
a low-heat generating component disposed in the second region, and having a quantity of heat less than a quantity of heat of the high-heat generating component.

6. The battery module of claim 5, wherein the high-heat generating component includes at least one of a HV (high-voltage) connector, a circuit breaker, a current sensor, and a Metal Oxide Semiconductor Field Effect Transistor (MOSFET).

7. The battery module of claim 5, wherein the low-heat generating component includes a LV (low-voltage) connector.

8. The battery module of claim 7, wherein the BMS module further includes a cooling element connection wire electrically connecting the LV connector and the cooling element.

9. The battery module of claim 8, wherein the cooling element connection wire has one end disposed on the second region of the substrate and the other end disposed on the first region of the substrate, and is connected to the cooling element.

10. The battery module of claim 4, further comprising: a busbar assembly electrically connected to at least one battery cell among the plurality of battery cells; and
a sensing module connected to the busbar assembly and sensing current and voltage of the at least one battery cell,
wherein the first region of the substrate is connected to the busbar assembly, and the second region of the substrate is connected to the sensing module.

11. The battery module of claim 2, wherein the thermoelectric device includes at least one of a Peltier element, a Seebeck element, and a Thomson element.
